(19) United States
(12) Patent Application Publication
(10) Pub. No.: US 2023/0407451 A1
(43) Pub. Date: Dec. 21, 2023

(54) MASK ASSEMBLY, METHOD OF MANUFACTURING MASK ASSEMBLY, AND METHOD OF MANUFACTURING DISPLAY APPARATUS

(71) Applicant: Samsung Display Co., Ltd., Yongin-si (KR)

(72) Inventors: Areum Lee, Yongin-si (KR); Hwi Kim, Yongin-si (KR); Kyuhwan Hwang, Yongin-si (KR); Jeongkuk Kim, Yongin-si (KR); Seungyong Song, Yongin-si (KR); Eunbee Jo, Yongin-si (KR)

(73) Assignee: Samsung Display Co., Ltd., Yongin-si (KR)

(21) Appl. No.: 18/313,607

(22) Filed: May 8, 2023

(30) Foreign Application Priority Data
Jun. 17, 2022 (KR) 10-2022-0074334

(51) Int. Cl. C23C 14/04

(52) U.S. Cl. CPC C23C 14/042

(57) ABSTRACT

A method of manufacturing a mask assembly includes preparing a mask frame including an opening area, forming an opening of a first group in a first area of a center of a mask sheet, tensioning and fixing the mask sheet to the mask frame, and forming an opening of a second group in a second area of the mask sheet. The second area surrounds the first area.

### CROSS-REFERENCE TO RELATED APPLICATION(S)

This application claims priority to and benefits of Korean Patent Application No. 10-2022-0074334 under 35 U.S.C. § 119, filed on Jun. 17, 2022 in the Korean Intellectual Property Office (KIPO), the entire contents of which are incorporated herein by reference.

### BACKGROUND

### 1. Technical Field

One or more embodiments relate to a mask assembly, a method of manufacturing a mask assembly, and a method of manufacturing a display apparatus, capable of improving deposition quality of a deposition material.

### 2. Description of the Related Art

Electronic apparatuses are widely used. Electronic apparatuses are variously used as mobile electronic apparatuses and fixed electronic apparatuses. To support various functions, the electronic apparatus includes a display apparatus which may provide visual information such as images to users.

A display apparatus is an apparatus configured to visually display data and may be formed by depositing various layers such as an organic layer, a metal layer, and the like. A deposition material may be deposited to form multiple layers of a display apparatus. For example, the deposition material from a deposition source may be sprayed and deposited on a substrate through a mask assembly. In the case where transformation of a mask sheet occurs, the deposition material may not be deposited on a required position of the substrate, and thus, a deposition quality is deteriorated.

It is to be understood that this background of the technology section is, in part, intended to provide useful background for understanding the technology. However, this background of the technology section may also include ideas, concepts, or recognitions that were not part of what was known or appreciated by those skilled in the pertinent art prior to a corresponding effective filing date of the subject matter disclosed herein.

### SUMMARY

One or more embodiments include a mask assembly, a method of manufacturing a mask assembly, and a method of manufacturing a display apparatus, capable of improving a deposition quality of a deposition material by preventing the shape of an opening of a mask sheet from being transformed.

However, such a technical aspect is only an example, and the disclosure is not limited thereto.

Additional aspects will be set forth in part in the description which follows and, in part, will be apparent from the description, or may be learned by practice of the embodiments of the disclosure.

According to one or more embodiments, a method of manufacturing a mask assembly may include preparing a mask frame including an opening area, forming an opening of a first group in a first area of a center of a mask sheet, tensioning and fixing the mask sheet to the mask frame, and forming an opening of a second group in a second area of the mask sheet. The second area may surround the first area.

The forming of the opening of the first group may include wet-etching the first area.

The forming of the opening of the second group may include laser-etching the second area.

The forming of the opening of the second group may include processing the opening of the second group such that the opening of the second group surrounds the first area.

The forming of the opening of the second group may include sequentially performing the laser-etching in a clockwise or counterclockwise direction around a reference point located in a center of the mask sheet.

The forming of the opening of the second group may include performing the laser-etching to form a first opening, and performing the laser-etching to form a second opening symmetrical to the first opening with respect to a reference point located in a center of the mask sheet.

The laser-etching of the second area may include laser-etching the second area in a size less than a size of the opening of the second group, and extending a laser-etched portion to the size of the opening of the second group by using tensile force applied to the mask sheet.

The tensioning and fixing of the mask sheet to the mask frame may include welding a third area to the mask frame. The third area may surround the second area of the mask sheet.

The forming of the opening of the second group may include performing wet-etching to form a temporary opening less than a size of the opening of the second group, and performing laser-etching along a circumference of the temporary opening.

The temporary opening may be formed in an operation of wet-etching, and the operation of wet-etching and the wet-etching of forming the opening of the first group may be a same operation.

A shape of the temporary opening and a shape reduced by offsetting a shape of the opening of the second group by a same ratio are same.

The forming of the opening of the second group may include half-etching the second area to correspond to a size of the opening of the second group in a first surface of the mask sheet, and laser-etching the second area in a second surface of the mask sheet facing the first surface.

The half-etching of the second area may include half-etching the second area by using a wet-etching method.

The forming of the opening of the first group may include half-etching the first area to correspond to a size of the opening of the first group in the first surface, and half-etching the first area in the second surface.

The half-etching of the second area in the first surface may be performed in a same process as a process of half-etching the first area in the first surface.

According to one or more embodiments, a method of manufacturing a display apparatus may include preparing a mask assembly, arranging a display substrate to face the mask assembly, and passing a deposition material through the mask assembly and depositing the deposition material on the display substrate, the deposition material being supplied from a deposition source. The preparing of the mask assembly may include preparing a mask frame including an opening area, forming an opening of a first group in a first area of a center of a mask sheet, tensioning and fixing the mask sheet to the mask frame, and forming an opening of a second group in a second area of the mask sheet. The second area may surround the first area.

The forming of the opening of the first group may include wet-etching the first area.

The forming of the opening of the second group may include laser-etching the second area.

According to one or more embodiments, a mask assembly may include a mask frame including an opening area, and a mask sheet arranged within the opening area. The mask sheet may include a first area in a center, having an opening of a first group, and a second area having an opening of a second group and surrounding the first area. The first area may have a first inclined surface in a thickness direction in a circumference of the opening of the first group. The second area may have a second inclined surface in the thickness direction in a circumference of the opening of the second group. An inclined angle of the first inclined surface may be different from an inclined angle of the second inclined surface.

The first inclined surface may be a curved surface, and the second inclined surface may be a flat surface.

These and/or other aspects will become apparent and more readily appreciated from the following description of the embodiments, the accompanying drawings, and claims.

### BRIEF DESCRIPTION OF THE DRAWINGS

The above and other aspects, features, and advantages of certain embodiments of the disclosure will be more apparent from the following description taken in conjunction with the accompanying drawings, in which:

FIG. 1 is a schematic cross-sectional view of an apparatus for manufacturing a display apparatus according to an embodiment;

FIG. 2 is a schematic perspective view of a mask assembly according to an embodiment;

FIGS. 3 to 6B are schematic plan views showing a method of manufacturing a mask assembly according to an embodiment;

FIG. 7 is a schematic plan view showing a method of processing openings of a second group;

FIG. 8 is a schematic plan view showing another method of processing openings of a second group;

FIG. 9 is a schematic cross-sectional view of a mask assembly manufactured according to a method of manufacturing a mask assembly, taken along line IX-IX′ of FIG. 6A;

FIG. 10 is a schematic view for comparing a portion of the mask assembly of FIG. 9;

FIGS. 11 to 13 are schematic views showing a method of manufacturing a mask assembly according to another embodiment;

FIGS. 14A to 18 are schematic views showing a method of manufacturing a mask assembly according to another embodiment;

FIG. 19 is a schematic plan view of a display apparatus manufactured by an apparatus of manufacturing a display apparatus according to an embodiment; and

FIG. 20 is a schematic cross-sectional view of a display apparatus manufactured by an apparatus of manufacturing a display apparatus according to an embodiment, taken along line XX-XX′ of FIG. 19.

### DETAILED DESCRIPTION OF THE EMBODIMENTS

Reference will now be made in detail to embodiments, examples of which are illustrated in the accompanying drawings, wherein like reference numerals refer to like elements throughout. In this regard, the embodiments may have different forms and should not be construed as being limited to the descriptions set forth herein. Accordingly, the embodiments are merely described below, by referring to the figures, to explain aspects of the description.

As used herein, the singular forms, “a,” “an,” and “the” are intended to include the plural forms as well, unless the context clearly indicates otherwise.

In the specification and the claims, the term “and/or” is intended to include any combination of the terms “and” and “or” for the purpose of its meaning and interpretation. For example, “A and/or B” may be understood to mean any combination including “A, B, or A and B.” The terms “and” and “or” may be used in the conjunctive or disjunctive sense and may be understood to be equivalent to “and/or.

In the specification and the claims, the phrase “at least one of” is intended to include the meaning of “at least one selected from the group of” for the purpose of its meaning and interpretation. For example, “at least one of A and B” may be understood to mean any combination including “A, B, or A and B.”

While such terms as “first” and “second” may be used to describe various components, such components must not be limited to the above terms. The above terms are used to distinguish one component from another.

The terms “comprises,” “comprising,” “includes,” and/or “including,”, “has,” “have,” and/or “having,” and variations thereof when used in this specification, specify the presence of stated features, integers, steps, operations, elements, components, and/or groups thereof, but do not preclude the presence or addition of one or more other features, integers, steps, operations, elements, components, and/or groups thereof.

It will be further understood that, when a layer, region, or component is referred to as being “on” another layer, region, or component, it can be directly or indirectly on the other layer, region, or component. For example, intervening layers, regions, or components may be present.

Sizes of elements in the drawings may be exaggerated or reduced for convenience of explanation. As an example, the size and thickness of each element shown in the drawings are arbitrarily represented for convenience of description, and thus, the disclosure is not necessarily limited thereto.

The X-axis, the Y-axis and the Z-axis are not limited to three axes of the rectangular coordinate system, and may be interpreted in a broader sense. For example, the X-axis, the Y-axis, and the Z-axis may be perpendicular to one another, or may represent different directions that are not perpendicular to one another.

In the case where a certain embodiment may be implemented differently, a specific process order may be performed in the order different from the described order. As an example, two processes successively described may be simultaneously performed substantially or may be performed in an opposite order.

The terms “face” and “facing” mean that a first element may directly or indirectly oppose a second element. In a case in which a third element intervenes between the first and second element, the first and second element may be understood as being indirectly opposed to one another, although still facing each other.

“About” or “approximately” as used herein is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” may mean within one or more standard deviations, or within ±30%, 20%, 10%, 5% of the stated value.

Unless otherwise defined, all terms (including technical and scientific terms) used herein have the same meaning as commonly understood by one of ordinary skill in the art to which the disclosure pertains. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

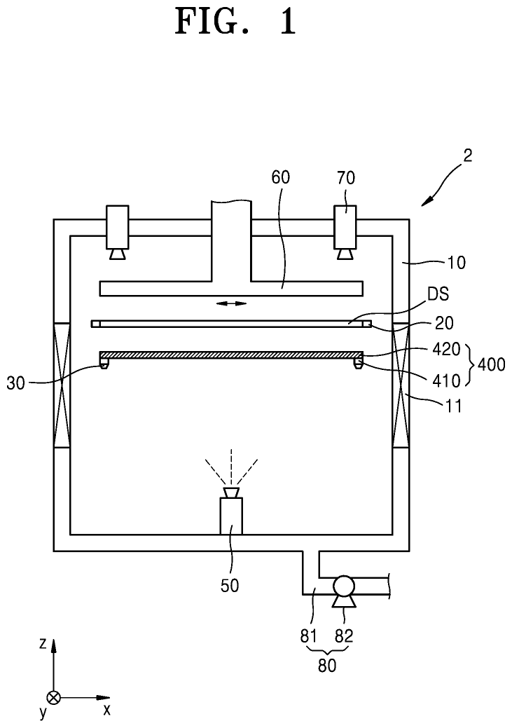

FIG. 1 is a schematic cross-sectional view of an apparatus 2 for manufacturing a display apparatus according to an embodiment.

The apparatus 2 for manufacturing a display apparatus may include a chamber 10, a first supporter 20, a second supporter 30, a mask assembly 400, a deposition source 50, a magnetic force portion 60, a vision portion 70, and a pressure adjustor 80.

A space may be formed inside the chamber 10. A display substrate DS and the mask assembly 400 may be received in the space. A portion of the chamber 10 may be formed to be open. A gate valve 11 may be installed in the open portion of the chamber 10. The open portion of the chamber 10 may be opened or closed according to an operation of the gate valve 11.

The display substrate DS may denote the display substrate DS in which at least one of an organic layer, an inorganic layer, and a metal layer is deposited on the substrate 100 described below while the display apparatus is manufactured. In other embodiments, the display substrate DS may be the substrate 100 on which any of the organic layer, the inorganic layer, and the metal layer is not yet deposited.

The first supporter 20 may be configured to support the display substrate DS. The first supporter 20 may be a plate form fixed inside the chamber 10. In another embodiment, the first supporter 20 may be a shuttle form in which the display substrate DS is seated and which is linearly movable inside the chamber 10. In another embodiment, the first supporter 20 may include an electrostatic chuck or an adhesive chuck disposed in the chamber 10 to be fixed or movable inside the chamber 10.

The second supporter 30 may be configured to support the mask assembly 400. The second supporter 30 may be disposed inside the chamber 10. The second supporter 30 may finely-adjust the position of the mask assembly 400. The second supporter 30 may include a driver, an alignment unit, or the like separately to move the mask assembly 400 in different directions.

In another embodiment, the second supporter 30 may be a shuttle form. The mask assembly 400 may be seated on the second supporter 30. The second supporter may be configured to transfer the mask assembly 400. As an example, the second supporter 30 may move to the outside of the chamber 10, and after the mask assembly 400 is seated on the second supporter 30, and the second supporter 30 may enter the chamber 10 from the outside of the chamber 10.

The first supporter 20 and the second supporter 30 may be integrally formed with each other. The first supporter 20 and the second supporter 30 may include a movable shuttle. The first supporter 20 and the second supporter 30 may include a structure configured to fix the mask assembly 400 to the display substrate DS with the display substrate DS seated on the mask assembly 400, and be configured to linearly move the display substrate DS and the mask assembly 400 simultaneously.

Hereinafter, for convenience of description, a form in which the first supporter and the second supporter 30 are formed to be discriminated from each other and arranged in different positions, and a form in which the first supporter 20 and the second supporter 30 are disposed inside the chamber 10, are described in detail.

The deposition source 50 may be disposed to face the mask assembly 400. A deposition material may be received in the deposition source 50. The deposition material may be evaporated or sublimated by applying heat to the deposition material. The deposition source 50 may be disposed to be fixed inside the chamber 10, or disposed inside the chamber to be linearly moved in a direction.

The mask assembly 400 may be disposed inside the chamber 10. The mask assembly 400 may include a mask frame 410 and a mask sheet 420. This is described below in detail. The deposition material may pass through the mask assembly 400 and be deposited on the display substrate DS.

The magnetic force portion 60 may be disposed inside the chamber 10 to face the display substrate DS and/or the mask assembly 400. The magnetic force portion may apply magnetic force to the mask assembly 400 and press the mask assembly 400 toward the display substrate DS. Particularly, the magnetic force portion 60 may not only prevent sagging of the mask sheet 420 but allow the mask sheet 420 to be adjacent to the display substrate DS. The magnetic force portion 60 may maintain a uniform interval between the mask sheet 420 and the display substrate DS.

The vision portion 70 may be disposed in the chamber 10 and may photograph the positions of the display substrate DS and the mask assembly 400. The vision portion 70 may include a camera configured to photograph the display substrate DS and the mask assembly 400. The positions of the display substrate DS and the mask assembly 400 may be determined based on the images photographed by the vision portion 70, and the transformation of the mask assembly 400 may be determined. The first supporter 20 may be configured to finely-adjust the position of the display substrate DS or the second supporter 30 may be configured to finely-adjust the position of the mask assembly 400 based on the photographed images. Hereinafter, the case wherein the second supporter 30 is configured to finely-adjust the position of the mask assembly 400 and align the positions of the display substrate DS and the mask assembly 400, is described in detail.

The pressure adjustor 80 may be connected to the chamber 10 and configured to adjust the inner pressure of the chamber 10. As an example, the pressure adjustor may be configured to adjust the inner pressure of the chamber 10 to be equal or similar to the atmospheric pressure. The pressure adjustor 80 may be configured to adjust the inner pressure of the chamber 10 to be equal or similar to a vacuum state.

The pressure adjustor 80 may include a connection pipe 81 and a pump 82, wherein the connection pipe 81 is connected to the chamber 10, and the pump 82 is installed to the connection pipe 81. External air may be introduced through the connection pipe 81 or a gas inside the chamber 10 may be guided to the outside through the connection pipe 81 according to an operation of the pump 82.

A method of manufacturing a display apparatus (not shown) by using the apparatus 2 for manufacturing a display apparatus, is described. First, the display substrate DS may be prepared.

The pressure adjustor 80 may maintain the inside of the chamber 10 at a state equal or similar to the atmospheric pressure. The gate valve 11 may operate to open the open portion of the chamber 10.

The display substrate DS may be loaded into the inside of the chamber 10 from the outside. The display substrate DS may be loaded into the chamber 10 in various methods. As an example, the display substrate DS may be loaded into the inside of the chamber 10 from the outside of the chamber 10 by a robot arm arranged outside the chamber 10. In another embodiment, in the case where the first supporter 20 is formed in a shuttle form, the first supporter 20 may be carried from the inside of the chamber 10 to the outside of the chamber 10, the display substrate DS may be seated on the first supporter 20 by a robot arm (e.g., separate robot arm) arranged outside the chamber 10, and the first supporter 20 may be loaded into the inside of the chamber from the outside of the chamber 10.

The mask assembly 400 may be arranged inside the chamber 10 as described above. In another embodiment, in the same or similar manner to the display substrate DS, the mask assembly 400 may be loaded into the inside of the chamber 10 from the outside of the chamber 10.

In case that the display substrate DS is loaded into the inside of the chamber the display substrate DS may be seated on the first supporter 20. The vision portion may be configured to photograph the positions of the display substrate DS and the mask assembly 400. The positions of the display substrate DS and the mask assembly 400, may be determined based on images photographed by the vision portion 70. The apparatus 2 for manufacturing a display apparatus may include a separate controller (not shown) to determine the positions of the display substrate DS and the mask assembly 400.

In case that the determination of the positions of the display substrate DS and the mask assembly 400 is completed, the second supporter 30 may finely-adjust the position of the mask assembly 400.

The deposition source 50 may operate to supply the deposition material toward the mask assembly 400, and the deposition material passing through openings of the mask sheet 420 may be deposited on the display substrate DS. The deposition source 50 may move in parallel to the display substrate DS and the mask assembly 400, or the display substrate DS and the mask assembly 400 may move in parallel to the deposition source 50. For example, the deposition source 50 may relatively move with respect to the display substrate DS and the mask assembly 400. The pump 82 may maintain the pressure of the chamber 10 at a state equal or similar to vacuum by sucking in the gas inside the chamber 10 and discharging the gas to the outside.

As described above, the deposition material supplied from the deposition source 50 may pass through the mask assembly 400, be deposited on the display substrate DS, and thus, form at least one of multiple layers, for example, an organic layer, an inorganic layer, and a metal layer stacked in the display apparatus described below.

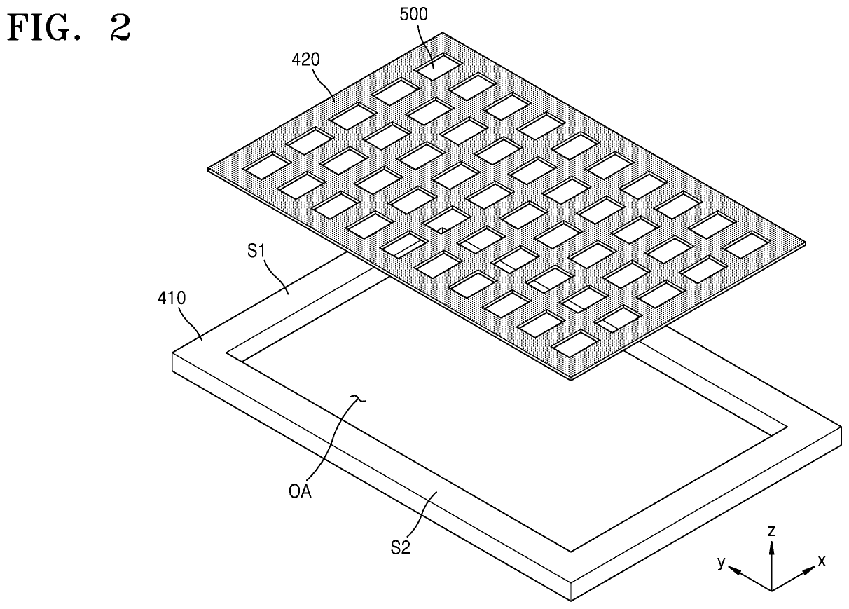

FIG. 2 is a schematic perspective view of the mask assembly 400 according to an embodiment and shows the mask assembly 400 that may be used in the apparatus for manufacturing a display apparatus.

Referring to FIG. 2, the mask assembly 400 may include the mask frame 410 and the mask sheet 420.

The mask frame 410 may include sides connected to each other and include an opening area OA defined by the sides. For example, the opening area OA may be surrounded by the sides and may pass through the center of the mask frame 410.

In an embodiment, a support stick (not shown) may be arranged to cross the opening area OA of the mask frame 410. The support stick may prevent sagging of the mask sheet 420 by supporting the mask sheet 420 in the opening area OA.

In an embodiment, the mask frame 410 may be a quadrangular frame. However, the shape of the mask frame 410 is not limited thereto but may be various polygonal shapes. Hereinafter, for convenience of description, the case where the mask frame 410 is a quadrangular frame, is described.

In the case where the mask frame 410 is a quadrangular frame, the sides may include a first side S1 extending in a first direction (e.g., the x direction in FIG. 2) and a second side S2 extending in a second direction (e.g., the y direction in FIG. 2) crossing (intersecting) the first direction. Because the first side S1 is provided as a pair to face each other, and the second side S2 is provided as a pair to face each other, the first side S1 may be connected to the second side S2. In an embodiment, the first side S1 may be a short side, and the second side S2 may be a long side. However, embodiments are not limited thereto but the first side S1 may be a long side and the second side S2 may be a short side, or the length of the first side S1 may be equal to the length of the second side S2. Hereinafter, for convenience of description, the case where the first side S1 is a short side and the second side S2 is a long side, is described.

The mask sheet 420 may be tensioned and installed to the mask frame 410. The opening area OA in the center of the mask frame 410 may be covered by the mask sheet 420. In an embodiment, the mask sheet 420 may be greater than the size of the opening area OA and disposed on the mask frame 410 while completely covering the opening area OA. The circumference of the mask sheet 420 may be fixed to the mask frame 410 by welding, for example.

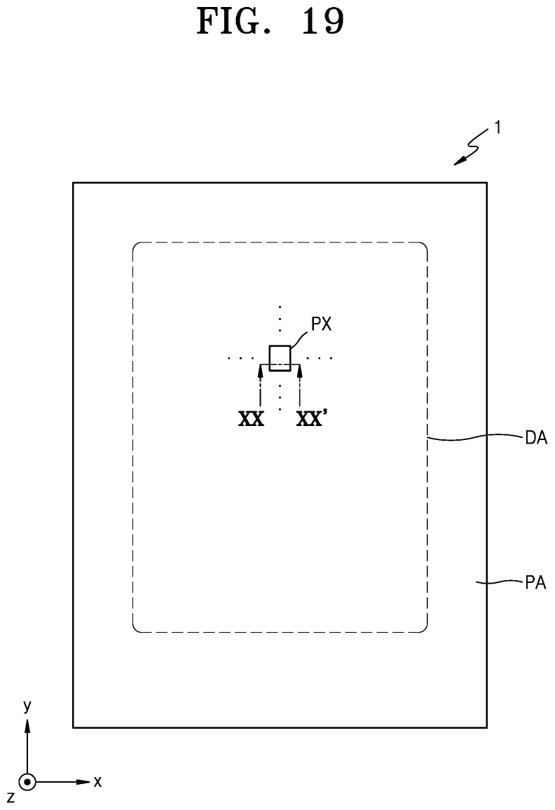

In an embodiment, openings 500 may be provided in the mask sheet 420. The opening 500 may be through holes formed such that the deposition material passes through the mask sheet 420. In an embodiment, the size of the openings 500 may be a size corresponding to a plane (see FIG. 19) including a display area DA and a peripheral area PA of the display apparatus, described below. Though it is shown in FIG. 2 that the shape of the opening 500 is quadrangular as an example, embodiments are not limited thereto but it may be understood that the shape of the opening 500 may be formed in a circular shape or a polygonal shape according to the planar shape of the display apparatus.

The openings 500 may be apart from each other and arranged in rows and columns. As an example, though the openings 500 may be configured in 10 rows and 5 columns as shown in FIG. 2, embodiments are not limited thereto but, it may be understood that, as the mask sheet 420 has a large area, the openings 500 may be configured in more rows and columns.

The deposition material passing through the mask sheet 420, specifically, the openings 500, may be deposited on the display substrate DS (see FIG. 1).

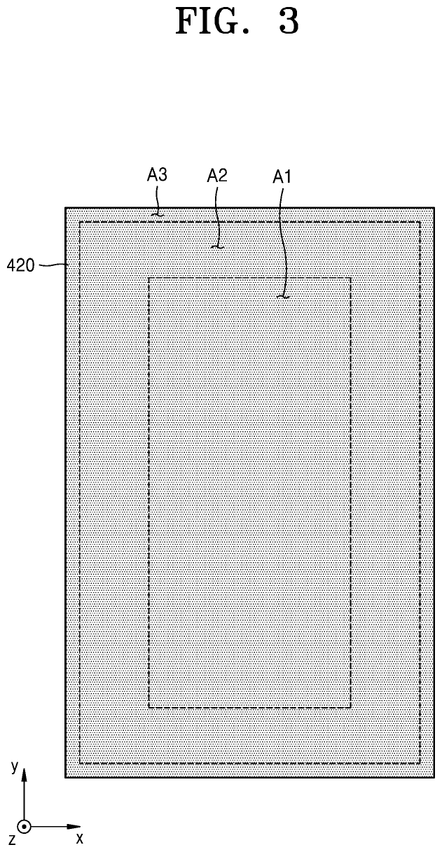

FIGS. 3 to 6B are schematic plan views showing a method of manufacturing a mask assembly according to an embodiment.

Referring to FIG. 3, the mask sheet 420 may be prepared. In an embodiment, the mask sheet 420 may include at least one of invar (for example, an alloy of about 64% iron (Fe) and about 36% nickel (Ni)), super invar (for example, an alloy with cobalt (Co) added to invar), nickel, and an alloy of nickel and cobalt. Accordingly, the mask sheet 420 may prevent an error in transformation due to temperature change by having a low thermal coefficient.

The mask sheet 420 may include a first area A1 and a second area A2 surrounding the first area A1 in a plan view, wherein the first area A1 is in the center. In an embodiment, as described below, the second area A2 may be a region corresponding to openings 500 in one column on the outermost portion arranged adjacent to the circumference of the mask sheet 420 among the openings 500. In other words, openings 520 of a second group may be arranged in a closed loop in one column in the second area A2. The first area A1 may be a region except for the second area A2 and may be a region in the center surrounded by the second area A2. Openings 510 of a first group may be arranged in the first area A1. This is described below in detail.

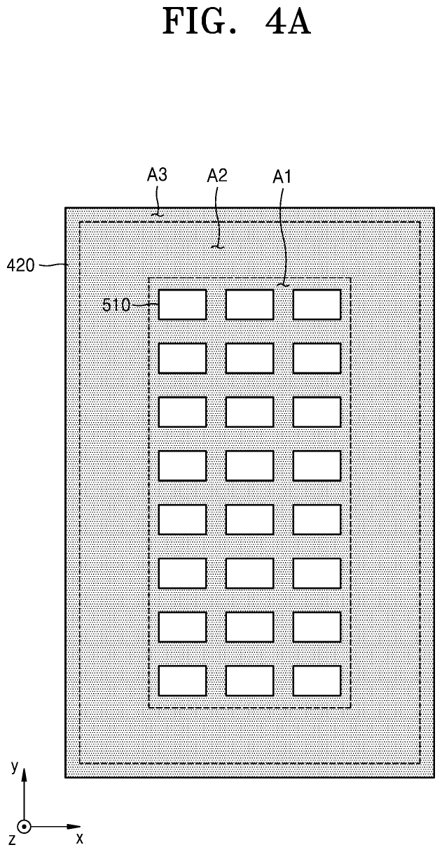

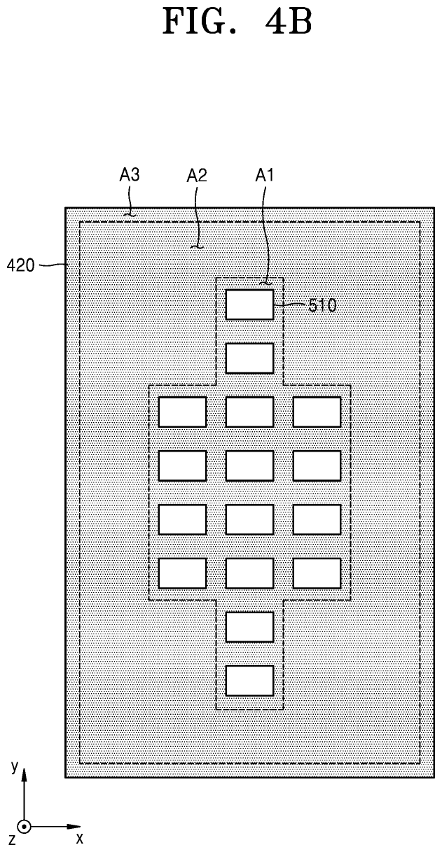

Referring to FIGS. 4A and 4B, the openings 500 may be formed in the mask sheet 420. Specifically, the openings 510 of the first group may be formed in the first area A1. The openings 510 of the first group may be apart from each other side by side in the first direction (e.g., the x direction in FIG. 4A) and the second direction (e.g., the y direction in FIG. 4A) crossing the first direction. Though it is shown in FIG. 4A that a profile of the first area A1 and a profile of an outer portion formed by the openings 510 of the first group arranged in the first area A1, are rectangular, embodiments are not limited thereto. As shown in FIG. 4B, the profile of the first area A1 and the profile of an outer portion formed by the openings 510 of the first group arranged in the first area A1, may be a cross (+) shape, or various shapes surrounded by the second area A2 though not shown in the drawing. Hereinafter, for convenience of description, as shown in FIG. 4A, the case where the profile of the first area A1 is rectangular, is described.

In an embodiment, the openings 510 of the first group arranged in the first area A1, may be formed by wet-etching. For example, the openings 510 of the first group may be formed by coating a photoresist, performing exposure, development, and wet-etching the exposed surface of the mask sheet 420. It is not excluded that the openings 510 of the first group are formed by other etching methods, for example, dry-etching or laser-etching. Hereinafter, for convenience of description, the case where the openings 510 of the first group are formed by wet-etching, is described.

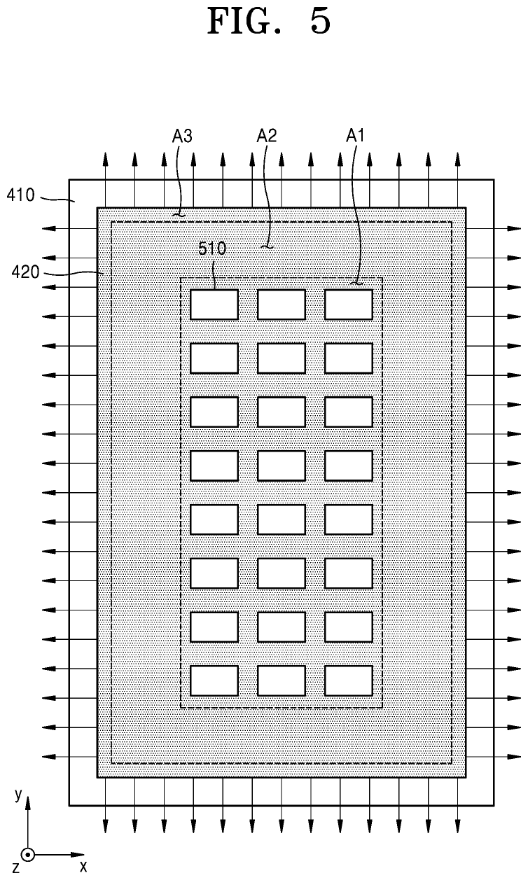

Referring to FIG. 5, the mask sheet 420 may be fixed to the mask frame 410 afterward. The mask sheet 420 may further include a third area A3 surrounding the second area A2 in the outside. The mask sheet 420 may be fixed to the mask frame 410 in the third area A3. In an embodiment, the mask sheet 420 may be fixed to the mask frame 410 by spot welding.

The mask sheet 420 may be fixed to the mask frame 410 while being tensioned. The mask sheet 420 may be clamped on its two opposite ends in the first direction (e.g., the x direction in FIG. 5) and on its two opposite ends in the second direction (e.g., the y direction in FIG. 5), and fixed to the mask frame 410 while being tensioned in the first direction and the second direction. This may complement (e.g., reduce) sagging of the mask sheet 420, particularly, the large-sized mask sheet 420, and improve deposition quality.

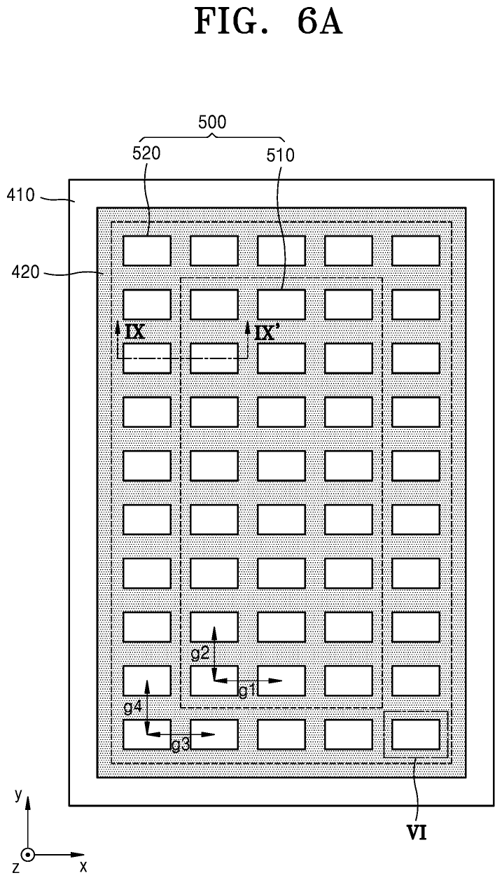

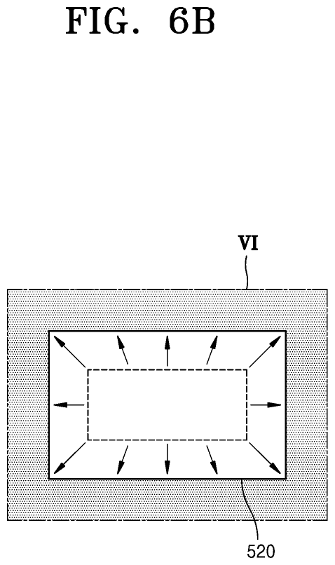

Referring to FIG. 6A, with the mask sheet 420 tensioned and fixed to the mask frame 410, the openings 520 of the second group may be formed in the second area A2. The openings 520 of the second group may be arranged to surround the openings 510 of the first group. The openings 520 of the second group may have substantially same size and substantially same shape as those of the openings 510 of the first group.

In an embodiment, the openings 520 of the second group may be the openings 500 on the outermost portion in a column arranged adjacent to the circumference of the mask sheet 420. However, this is an example, and as shown in FIG. 6A, it may be understood that the openings 520 of the second group may be arranged not only in one column but in two columns. The openings 520 of the second group may be the openings 520 arranged adjacent to the circumference of the mask sheet 420 and be the openings 520 arranged in a region to which relatively large tensile force corresponding to tension of the mask sheet 420 acts.

The openings 520 of the second group may be aligned with the same interval as the openings 510 of the first group. For example, an interval g3 in the first direction between the centers of two adjacent openings 520 among the openings 520 of the second group, may be equal to an interval g1 in the first direction between the centers of two adjacent openings 510 among the openings 510 of the first group. Likewise, an interval g4 in the second direction between the centers of two adjacent openings 520 among the openings 520 of the second group, may be equal to an interval g2 in the second direction between the centers of two adjacent openings 510 among the openings 510 of the first group.

In an embodiment, the openings 520 of the second group arranged in the second area A2, may be formed by laser-etching. For example, the openings 520 may be formed by processing the mask sheet 420 using a laser beam. The laser beam for the process may include a wavelength range between about 400 nm to about 600 nm in an embodiment. The openings 520 of the second group may be more precisely processed by the laser-etching.

FIG. 6B is an enlarged view of a region VI in FIG. 6A. Referring to FIG. 6B, because the openings 520 of the second group are processed with the mask sheet 420 tensioned, the openings 520 may be laser-etched in a size less than the size of completed openings 520 in an embodiment. For example, each of the through holes formed by the laser-etching may be extended by tensile force applied to the mask sheet 420, and completed as each of the openings 520.

As described above, because the openings 510 of the first group arranged in the first area A1 are formed, the mask sheet 420 is tensioned and fixed to the mask frame 410, and the openings 520 of the second group arranged in the second area A2 are formed, a precision of manufacturing the mask sheet 420 may improve and a deposition quality may improve.

Specifically, in the case where the openings 510 of the first group arranged in the first area A1 and the openings 520 of the second group arranged in the second area A2 are all formed and the mask sheet 420 is tensioned and fixed to the mask frame 410, the openings 500 may be transformed due to tensile force during the tensioning process. The transformation of the openings 500 may deteriorate the deposition quality.

In the case where the mask sheet 420 is tensioned and fixed to the mask frame 410, and the openings 510 of the first group and the openings 520 of the second group are formed, the laser-etching may be used, which may increase costs for the process and time for processing the openings.

According to embodiments, the openings 510 of the first group may be formed in advance in the first area A1 in the center which receives a relatively small influence of tensile force, and the openings 520 of the second group may be formed in the second area A2 which is tensioned and which receives a relatively large influence of the tensile force in the circumference. Accordingly, transformation due to the tensile force may be reduced.

Because the openings 520 of the second group are laser-etched, more precise processing may be performed, which may improve precision of the openings 520 of the second group that receives a relatively large influence of transformation due to the tensile force.

In an embodiment, because the openings 510 of the first group are formed by the wet-etching, the openings 510 of the first group may be processed relatively fast. The openings 520 of the second group may be more precisely processed because the openings 520 are formed by the laser-etching. Though a processing precision of the openings 510 of the first group in the first area A1 that receives a relatively small influence of the tensile force is reduced more or less compared to the case where openings are formed by the laser-etching, the quality may not be much influenced. Accordingly, because the openings 510 of the first group may be processed fast by the wet-etching, and the openings 520 of the second group are processed by the laser-etching after the mask sheet 420 is tensioned, transformation may be reduced. Accordingly, the processing precision and the processing efficiency of the mask assembly 400 may be optimized by trade-off.

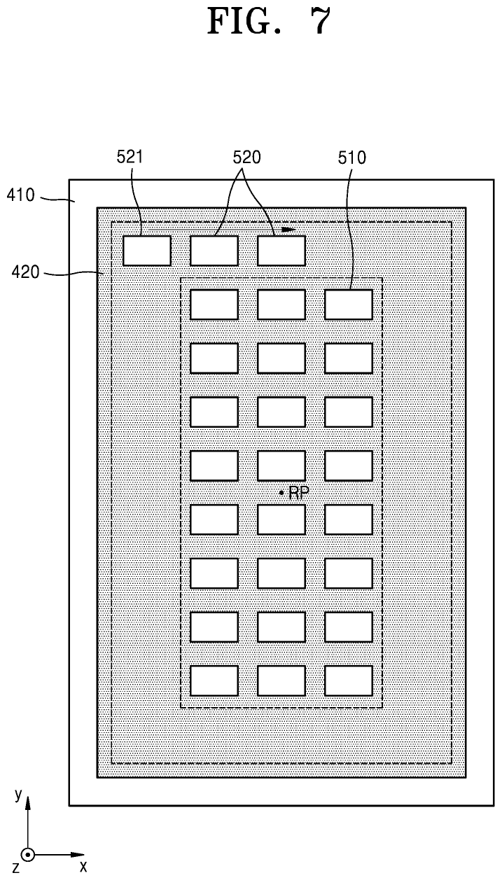

FIG. 7 is a schematic plan view showing a method of processing the openings 520 of the second group.

Referring to FIG. 7, the openings 520 of the second group may be sequentially processed in a clockwise direction based on a reference point RP located at the center of the mask sheet 420 in a plan view. In case that one of the openings 520 of the second group arranged at the corner in FIG. 7 is defined as a first opening 521, the openings 520 of the second group may be sequentially processed in a clockwise direction using the first opening 521 as a starting point.

In other embodiments, though not shown, the openings 520 of the second group may be processed from multiple starting points. For example, in an embodiment, in case that an opening 520 of the second group that is located in a diagonal direction with respect to the first opening 521, is defined as a second opening 522 (not shown), the openings 520 of the second group may be processed in a clockwise direction using the first opening 521 and the second opening 522 as starting points, respectively. In other embodiments, it may be understood that there are two or more starting points.

Though it is shown in FIG. 7 that the openings 520 of the second group are sequentially processed in a clockwise direction based on the reference point RP, it may be understood that the openings 520 of the second group may be sequentially processed in a counterclockwise direction based on the reference point RP.

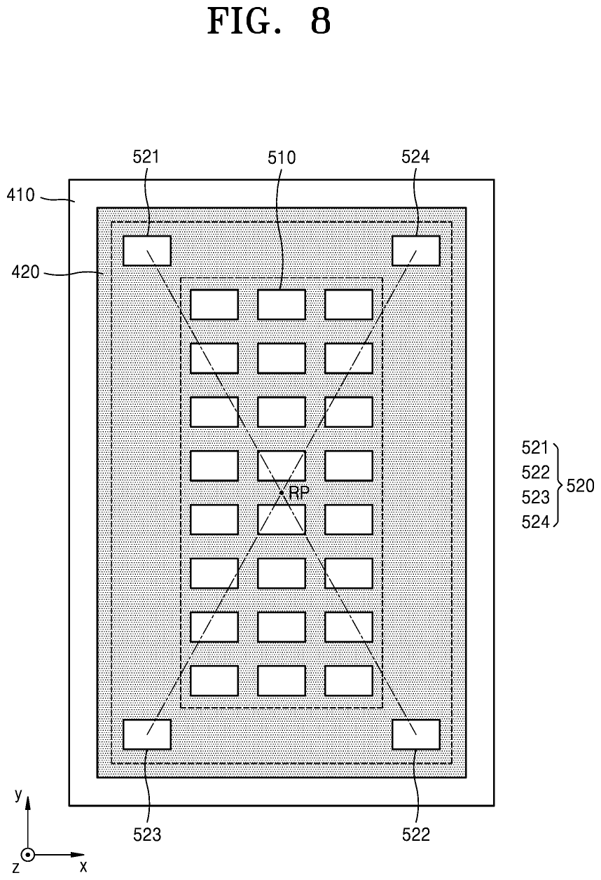

FIG. 8 is a schematic plan view showing a method of processing the openings 520 of the second group.

Referring to FIG. 8, in the openings 520 of the second group, the first openings 521 may be processed. The second opening 522 may be processed, wherein the second opening 522 is located at a position that is point-symmetrical to the first opening 521 with respect to the reference point RP located at the center of the mask sheet 420 in a plan view. For example, a third opening 523 may be processed, and a fourth opening 524 may be processed, wherein the third opening 523 is at another corner of the mask sheet 420, and the fourth opening 524 is located at a position that is point-symmetrical to the third opening 523. All of the openings 520 of the second group may be processed in this method. This may reduce non-uniformity in stress and non-uniformity in transformation inside the mask sheet 420 due to tensile force. Through this, reduction in the processing precision due to non-uniformity while the openings 520 of the second group are formed, may be reduced, and more accurate position and shape of the openings 520 may be obtained.

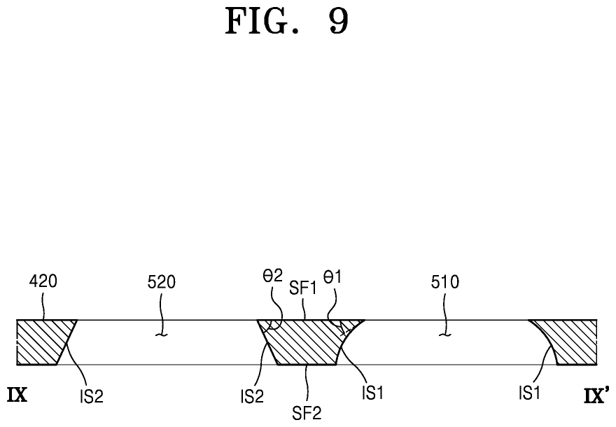

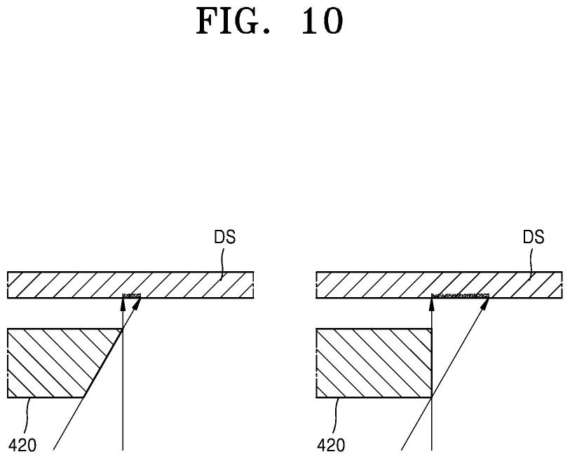

FIG. 9 is a schematic cross-sectional view of a mask assembly manufactured according to a method of manufacturing a mask assembly, taken along line IX-IX′ of FIG. 6A. FIG. 10 is a schematic view for comparing a portion of the mask assembly of FIG. 9.

Referring to FIG. 9, the first area A1 in which each of the openings 510 of the first group is defined, may have a first inclined surface IS1 in a thickness direction (e.g., a z direction in FIG. 9) in the circumference of each of the openings 510 of the first group. The second area A2 in which each of the openings 520 of the second group is defined, may have a second inclined surface IS2 in a thickness direction (e.g., the z direction in FIG. 9) in the circumference of each of the openings 520 of the second group.

A direction of the inclination of the first inclined surface IS1 and the second incline surface IS2, may be a direction in which the openings 500 gradually widens from a first surface SF1 (e.g., a surface in a +z direction in FIG. 9) of the mask sheet 420 arranged adjacent to the display substrate DS (see FIG. 1) to a second surface SF2 (e.g., a −z direction in FIG. 9) of the mask sheet 420 arranged adjacent to the deposition source 50 (see FIG. 1). In other words, the first inclined surface IS1 may have inclination such that a size of the openings 510 of the first group in the first surface SF1 is greater than a size of the openings 510 of the first group in the second surface SF2. The second inclined surface IS2 may have inclination such that a size of the openings 520 of the second group in the first surface SF1 is less than a size of the openings 520 of the second group in the second surface SF2.

FIG. 10 is a cross-sectional view of the mask assembly according to an embodiment. A deposition degree of the deposition materials of the case (the right side) where the size of the openings 500 in the second surface SF2 may be equal to the size of the openings 500 in the first surface SF1, is compared and shown. Referring to FIG. 10, because the first area A1 and the second area A2 include the first inclined surface IS1 and the second inclined surface IS2, a shadow phenomenon may be prevented. Specifically, as shown in the left side of FIG. 10, a shadow occurrence region in which the deposition material is blocked by the circumference of the openings 500 and not deposited in the second surface SF2, may be reduced. The quality of the display apparatus may be improved.

Referring to FIG. 9 again, in an embodiment, an inclination angle θ1 of the first inclined surface IS1 may be different from an inclination angle θ2 of the second inclined surface IS2. As an example, the inclination angle θ1 of the first inclined surface IS1 may be less than the inclination angle θ2 of the second inclined surface IS2. This is because the first inclined surface IS1 may be processed by the wet-etching and thus etched isotropically, and the second inclined surface IS2 may be processed by the laser-etching and thus anisotropically. In an embodiment, the inclination angle θ1 of the first inclined surface IS1 and the inclination angle θ2 of the second inclined surface IS2 may each have a value between about 30° to about 50°.

For the same reason, in an embodiment, the first inclined surface IS1 may include a curved surface, and the second inclined surface IS2 may include a flat surface.

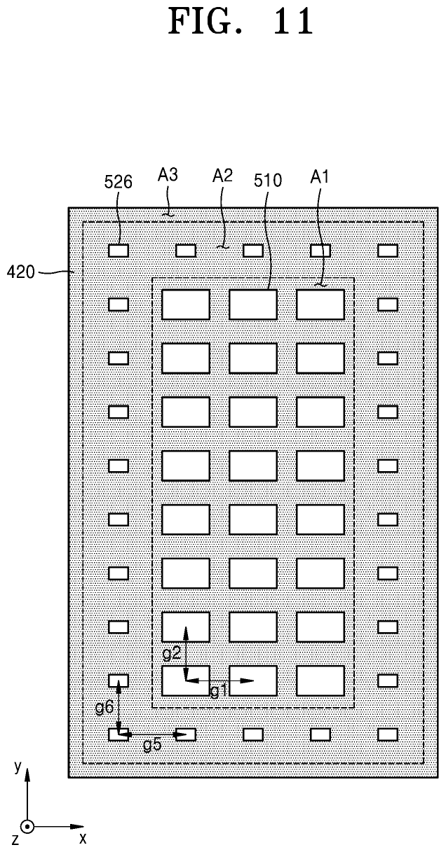

FIGS. 11 to 13 are schematic views showing a method of manufacturing a mask assembly according to another embodiment. In an embodiment, because a method of manufacturing a mask assembly may be similar to a previously described method of manufacturing a mask assembly, only differences are described for convenience of description.

Referring to FIG. 11, while the openings 510 of the first group are processed in the mask sheet 420, temporary openings 526 for the openings 520 of the second group may be processed together. In an embodiment, in the case where the openings 510 of the first group are processed by the wet-etching, the temporary openings 526 for the openings 520 of the second group may be processed by the same wet-etching.

Multiple temporary openings 526 may be provided and be apart from each other in the first direction (e.g., the x direction in FIG. 11) and the second direction (e.g., the y direction in FIG. 11) in the second area A2. Similar to the openings 520 of the second group, the temporary openings 526 may be arranged to surround the openings 510 of the first group, and arranged adjacent to the circumference of the mask sheet 420.

In an embodiment, the temporary openings 526 may be aligned with the same interval as the openings 510 of the first group. For example, an interval g5 in the first direction between the centers of two adjacent temporary openings 526 among the temporary openings 526, may be equal to the interval g1 in the first direction between the centers of two adjacent openings 510 among the openings 520 of the first group. Likewise, an interval g6 in the second direction between the centers of two adjacent temporary openings 526 among the temporary openings 526, may be equal to the interval g2 in the second direction between the centers of two adjacent openings 510 among the openings 520 of the first group.

In an embodiment, the temporary openings 526 may be processed in a size less than a size of the openings 520 of the second group. The temporary openings 526 may have a shape reduced by off-setting the openings 520 of the second group while having the same shape as a shape of the openings 520 of the second group. As an example, as shown in FIG. 11, the temporary openings 526 may have a rectangular shape, and the openings 520 of the second group may have a rectangular shape enlarged by off-setting the temporary openings 526 as described below. However, embodiments are not limited thereto. Though not shown in the drawing, the temporary openings 526 may have a square shape, a circular shape, or a cross (+) shape, and the openings 520 of the second group may have a rectangular shape as described below. Hereinafter, for convenience of description, the case where the temporary openings 526 have a rectangular shape and have a shape reduced by off-setting the openings 520 of the second group, is described.

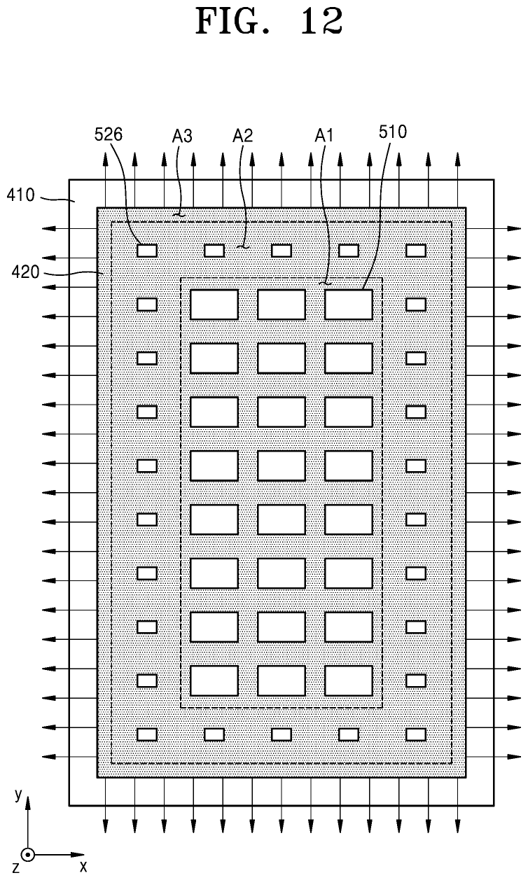

Referring to FIG. 12, the mask sheet 420 may be fixed to the mask frame 410 afterward. The mask sheet 420 may further include the third area A3 surrounding the second area A2 in the outside. The mask sheet 420 may be fixed to the mask frame 410 in the third area A3. In an embodiment, the mask sheet 420 may be fixed to the mask frame 410 by spot welding.

The mask sheet 420 may be fixed to the mask frame 410 while being tensioned. The mask sheet 420 may be clamped in its two opposite ends in the first direction (e.g., the x direction in FIG. 12) and in its two opposite ends in the second direction (e.g., the y direction in FIG. 12), and fixed to the mask frame 410 while being tensioned in the first direction and the second direction. This may complement (e.g., reduce) sagging of the mask sheet 420, particularly, the large-sized mask sheet 420, and improve deposition quality.

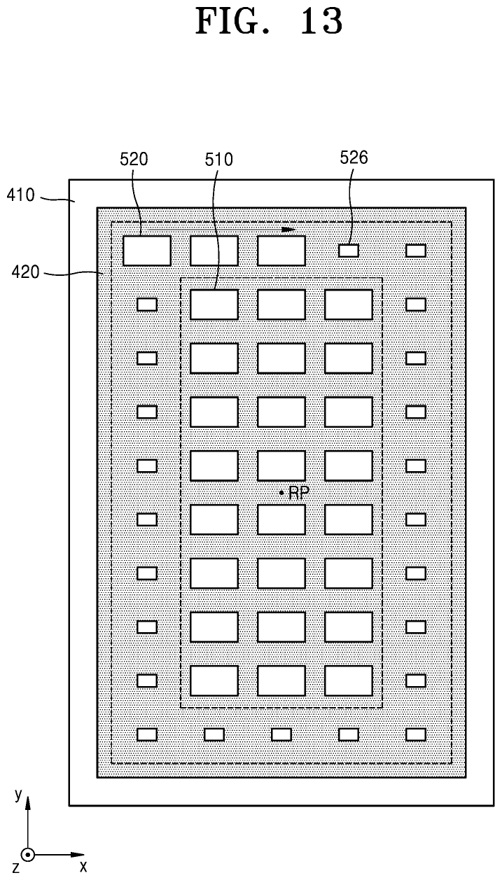

Referring to FIG. 13, with the mask sheet 420 tensioned and fixed to the mask frame 410, the openings 520 of the second group may be formed in the second area A2. The openings 520 of the second group may be processed based on the temporary openings 526. Specifically, each of the openings 520 of the second group may be processed by laser-etching the circumference of each of the temporary openings 526. In other words, the openings 520 of the second group may be processed by widening the temporary openings 526 using laser-processing. As described above, the openings 520 of the second group may have substantially same size and substantially same shape as those of the openings 510 of the first group.

Similar to that described with reference to FIG. 7, the openings 520 of the second group may be sequentially processed in a clockwise direction or a counterclockwise direction based on a reference point RP located at the center of the mask sheet 420 in a plan view. It will be understood that the openings 520 of the second group may be sequentially processed in a clockwise direction or a counterclockwise direction from multiple starting points.

In other embodiments, similar to that described with reference to FIG. 8, it will be understood that the openings 520 of the second group may be processed in a way in which the first opening 521 is processed and the second opening 522 is processed, wherein the second opening 522 is located at a position that is point-symmetrical to the first opening 521 with respect to the reference point RP located at the center of the mask sheet 420 in a plan view.

As described above, because the temporary openings 526 are processed in advance by the wet-etching, the mask sheet 420 is tensioned and fixed, and the openings 520 of the second group are processed, time taken for the process of manufacturing the mask assembly may be reduced. Processing all of the openings 520 of the second group by using laser-processing, respectively, may require multiple laser apparatuses or more process time. In contrast, according to an embodiment, because only a region excluding the sizes of the temporary openings 526 needs to be laser-processed, multiple laser apparatuses or more process time may not be required.

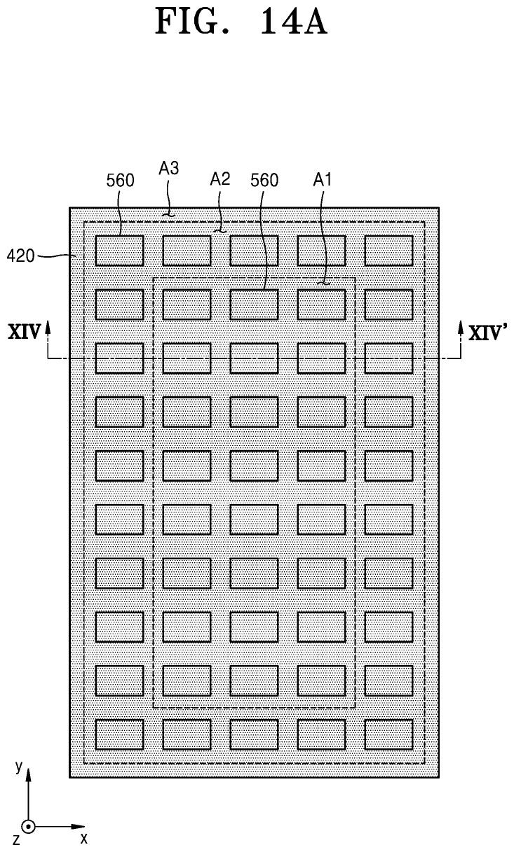

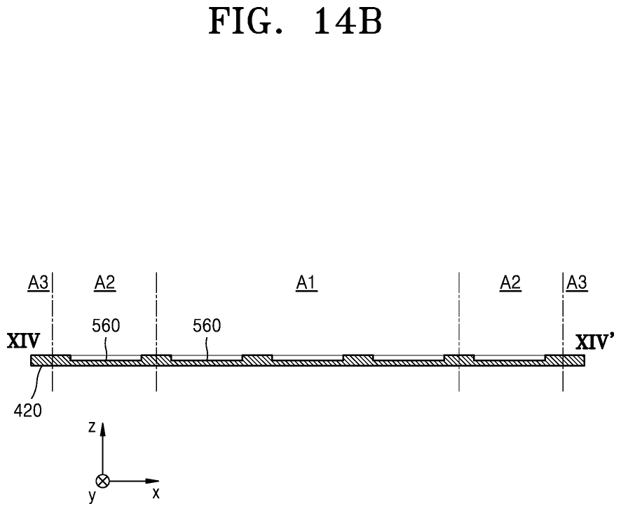

FIGS. 14A to 18 are schematic views showing a method of manufacturing a mask assembly according to another embodiment. In an embodiment, because a method of manufacturing a mask assembly is similar to a previously described method of manufacturing a mask assembly, only differences are described for convenience of description.

FIG. 14A is a plan view of the mask sheet 420, and FIG. 14B is a cross-sectional view of the mask sheet 420, taken along line XIV-XIV′.

Referring to FIGS. 14A and 14B, as described above, the mask sheet 420 may include the first surface SF1 and the second surface SF2, wherein the first surface SF1 is arranged to be adjacent to the display substrate DS (see FIG. 1), and the second surface SF2 is arranged to be adjacent to the deposition source 50 (see FIG. 1).

In an embodiment, the mask sheet 420 may be wet-etched, and the first surface SF1 may be half-etched. Specifically, to form the openings 510 of the first group and the openings 520 of the second group of the mask sheet 420, the first surface SF1 may be half-etched. For example, the first surface SF1 may be half-etched, at positions apart from each other in the first direction and the second direction, in sizes corresponding to the openings 510 of the first group and the openings 520 of the second group. Accordingly, multiple first half openings 560 may be formed, wherein the first half openings 560 are approximately half-etched in the thickness direction (e.g., the z direction in FIG. 14) from the first surface SF1. The first half openings 560 may be apart from each other in the first direction and the second direction. The first half openings 560 may be formed in the first area A1 and the second area A2. In case that the sizes of the first half openings 560 correspond to the sizes of the openings 510 of the first group and the openings 520 of the second group, it may mean that the sizes of the first half openings 560 may be the same or less than that the sizes of the openings 510, 520.

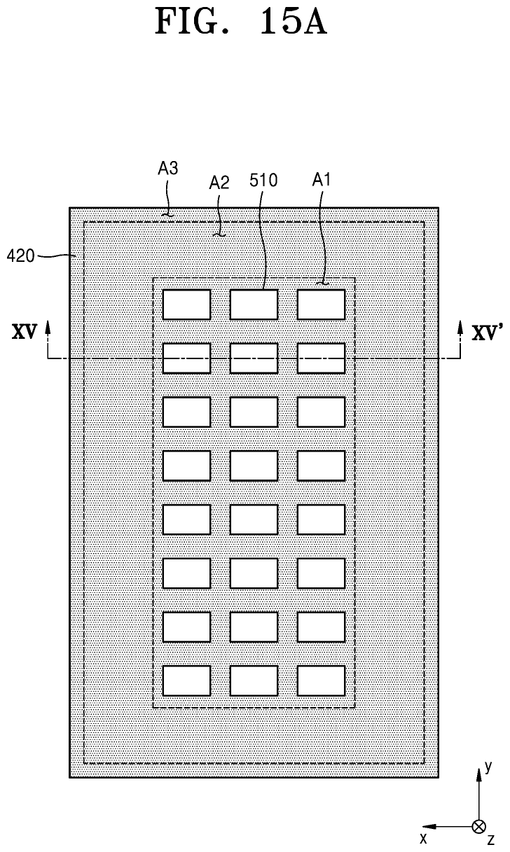

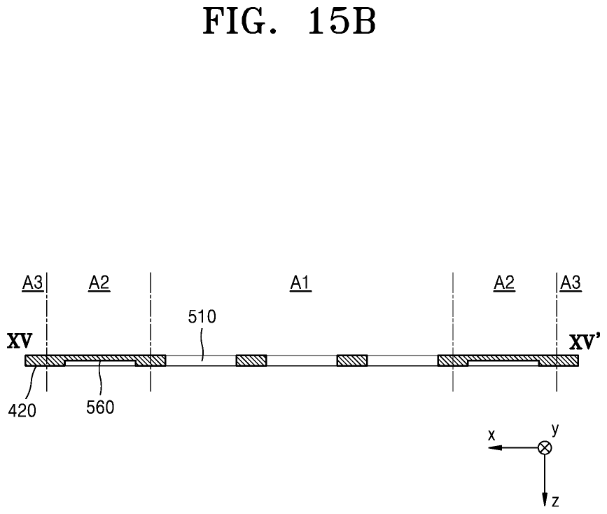

FIG. 15A is a backside view of the mask sheet 420, and FIG. 15B is a cross-sectional view of the mask sheet 420, taken along line XV-XV′.

Referring to FIGS. 15A and 15B, the mask sheet 420 may be wet-etched and the second surface SF may be half-etched. Specifically, to form the openings 510 of the first group of the mask sheet 420, the second surface SF2 may be half-etched. For example, as shown in FIG. 14, the second surface SF2 may be half-etched in sizes corresponding to the openings 510 of the first group on the opposite side of the first half openings 560 that are half-etched. Accordingly, multiple second half openings 570 may be formed, wherein the second half openings 570 are approximately half-etched in the thickness direction (e.g., the z direction in FIG. 15) from the second surface SF2. The second half openings 570 may be formed in the first area A1 and may not be formed in the second area A2. In other words, the second half openings 570 may be formed on the opposite side of the first half openings 560 formed in the first area A1 and may not be formed on the opposite side of the first half openings 560 formed in the second area A2.

Accordingly, as shown in FIG. 15, the openings 510 of the first group may be processed. The openings 510 of the first group may completely pass through the mash sheet 420 due to the first half openings 560 processed in the first surface SF1 and the second half openings 570 processed in the second surface SF2. Because while the second surface SF2 is half-etched, the second half openings 520 for the openings 520 of the second group are not processed in the second area A2, it will be understood that the openings 520 of the second group are not completed yet.

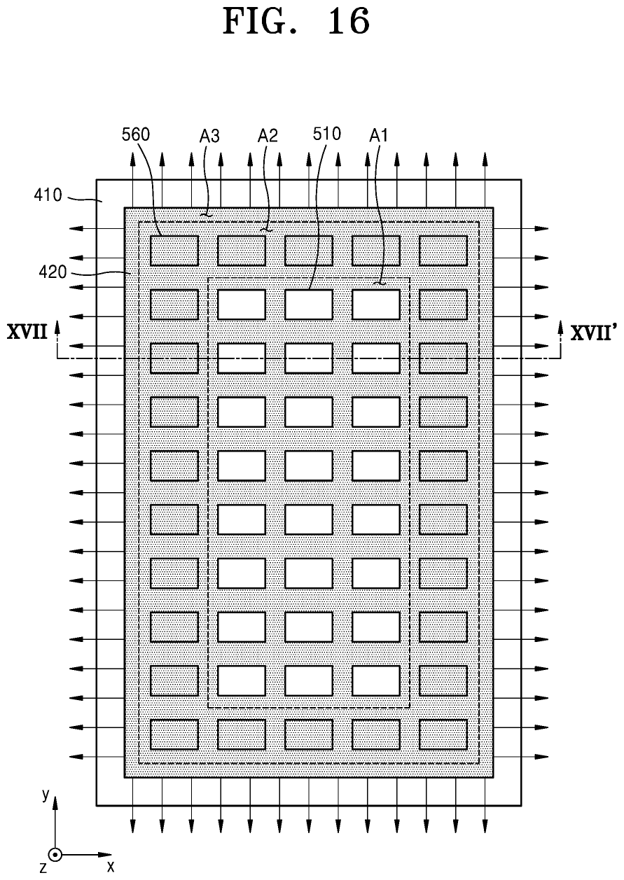

Referring to FIG. 16, the mask sheet 420 may be fixed to the mask frame 410. The mask sheet 420 may be tensioned and fixed to the mask frame 410. For fixing, the mask sheet 420 may be fixed to the mask frame by spot welding in an embodiment. This may be similar to the above process, and thus, detailed description thereof is omitted.

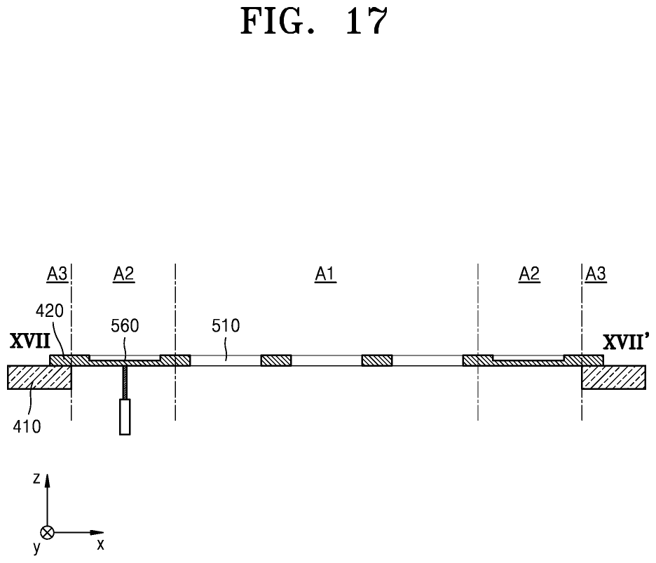

FIG. 17 is a cross-sectional view of the mask sheet 420, taken along line XVII-XVII′.

Referring to FIG. 17, with the mask sheet 420 tensioned and fixed to the mask frame 410, the openings 520 of the second group may be formed in the second area A2. The openings 520 of the second group may be processed based on the first half openings 560 processed in the second area A2. Specifically, the openings 520 of the second group may be formed by laser-etching the opposite side of the first half openings 560 in the second area A2. For example, the openings 520 of the second group may be formed by irradiating a laser beam to the second surface SF2 opposite the first surface SF1 in which the first half openings 560 are arranged. Because the mask sheet 420 is etched by about half in the thickness direction (e.g., the z direction in FIG. 17) due to the first half openings 560, the processing of the openings 520 of the second group may be more swiftly completed.

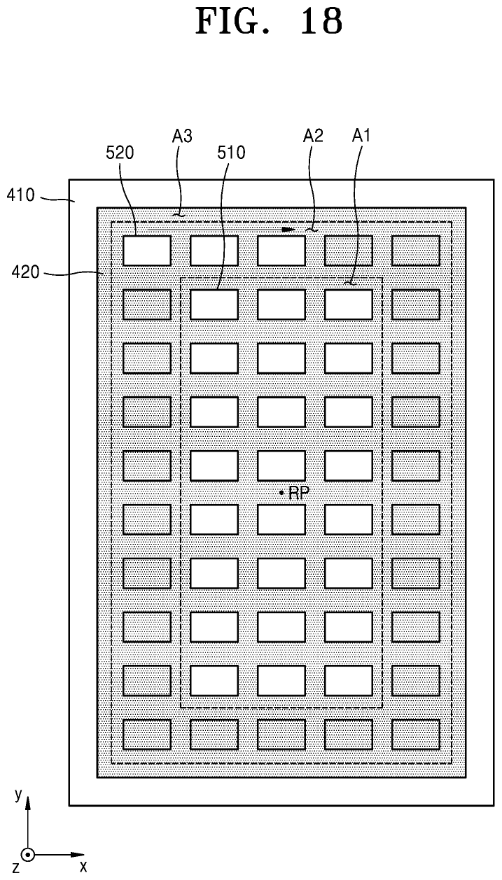

Referring to FIG. 18, similar to that described with reference to FIGS. 7 and 13, the openings 520 of the second group may be sequentially processed in a clockwise direction or a counterclockwise direction based on the reference point RP located at the center of the mask sheet 420 in a plan view. For example, the openings 520 of the second group may be sequentially processed by irradiating a laser beam to the second surface SF2 of the second area A2 in a clockwise direction or a counterclockwise direction based on the reference point RP, and etching the opposite side of the first half openings 560. It will be understood that the openings 520 of the second group may be sequentially processed in a clockwise direction or a counterclockwise direction from multiple starting points.

In other embodiments, similar to that described with reference to FIG. 8, it will be understood that the openings 520 of the second group may be processed in a way in which the first opening 521 is processed and the second opening 522 is processed, wherein the second opening 522 is located at a position that is point-symmetrical to the first opening 521 with respect to the reference point RP located at the center of the mask sheet 420 in a plan view.

As described above, because the first half openings 560 are processed in advance by the wet-etching, the mask sheet 420 is tensioned and fixed, and only the half of the thickness of the openings 520 of the second group are processed by irradiating a laser beam, time taken for the process of manufacturing the mask assembly may be reduced.

FIG. 19 is a schematic plan view of a display apparatus 1 manufactured by an apparatus of manufacturing a display apparatus according to an embodiment.

Referring to FIG. 19, the display apparatus 1 manufactured according to an embodiment, may include the display area DA and the peripheral area PA outside the display area DA. The display apparatus 1 may be configured to display images through an array of pixels PX arranged two-dimensionally in the display area DA.

The peripheral area PA may be a region that does not display images and may surround the display area DA entirely or partially. A driver and the like configured to provide electric signals or power to pixel circuits respectively corresponding to the pixels PX, may be arranged in the peripheral area PA. A pad may be arranged in the peripheral area PA, wherein the pad is a region to which electronic elements or a printed circuit board may be electrically connected.

Hereinafter, though the display apparatus 1 includes an organic light-emitting diode OLED as a light-emitting diode, the display apparatus 1 according to an embodiment is not limited thereto. In another embodiment, the display apparatus 1 may be a light-emitting display apparatus including an inorganic light-emitting diode, that is, an inorganic light-emitting display apparatus. The inorganic light-emitting diode may include a PN diode including inorganic material semiconductor-based materials. In case that a forward voltage is applied to a PN-junction diode, holes and electrons are injected and energy created by recombination of the holes and the electrons is converted to light energy, and thus, light of a preset color may be emitted. The inorganic light-emitting diode may have a width in the range of several micrometers to hundreds of micrometers. In an embodiment, the inorganic light-emitting diode may be denoted by a micro light-emitting diode. In another embodiment, the display apparatus 1 may be a quantum-dot light-emitting display apparatus.

The display apparatus 1 may be used as a display screen in various products including televisions, notebook computers, monitors, advertisement boards, Internet of things (IoT) apparatuses as well as portable electronic apparatuses including mobile phones, smart phones, tablet personal computers (PC), mobile communication terminals, electronic organizers, electronic books, portable multimedia players (PMP), navigations, and ultra mobile personal computers (UMPC). The display apparatus 1 according to an embodiment may be used in wearable devices including smartwatches, watchphones, glasses-type displays, and head-mounted displays (HMD). In an embodiment, the display apparatus 1 is used as a display screen in instrument panels for automobiles, center fascias for automobiles, or center information displays (CID) arranged on a dashboard, room mirror displays that replace side mirrors of automobiles, and displays arranged on the backside of front seats as an entertainment for back seats of automobiles.

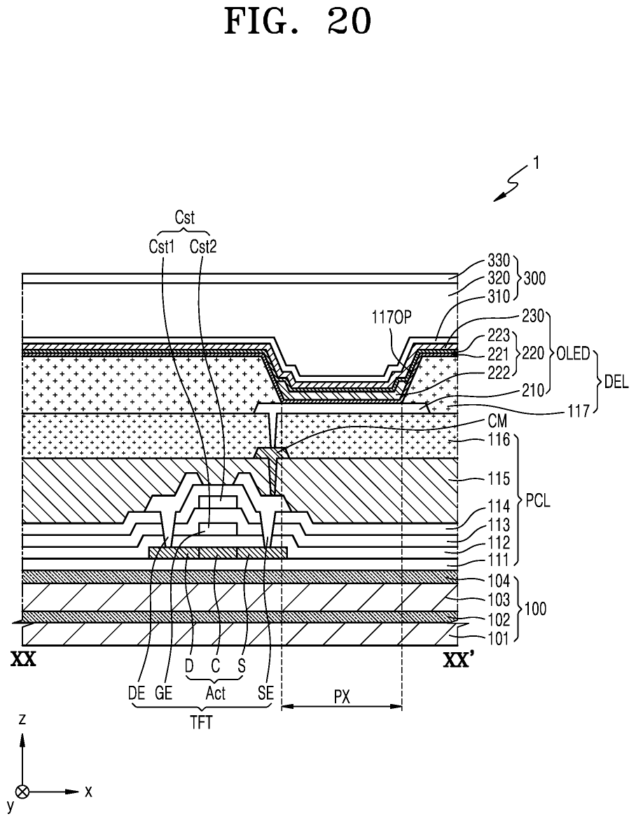

FIG. 20 is a schematic cross-sectional view of the display apparatus 1 manufactured by an apparatus of manufacturing a display apparatus according to an embodiment, taken along line XX-XX′ of FIG. 19.

Referring to FIG. 20, the display apparatus 1 may include a stack structure of a substrate 100, a pixel circuit layer PCL, a display element layer DEL, and an encapsulation layer 300. The display substrate DS (see FIG. 1) may be a structure in which at least one of, for example, the pixel circuit layer PCL, the display element layer DEL, and the encapsulation layer 300 is stacked on the substrate 100 during a process of manufacturing the display apparatus 1.

The substrate 100 may have a multi-layered structure including a base layer that includes the polymer resin and an inorganic layer. As an example, the substrate 100 may include the base layer including a polymer resin and a barrier layer including an inorganic insulating layer. As an example, the substrate 100 may include a first base layer 101, a first barrier layer 102, a second base layer 103, and a second barrier layer 104 that are sequentially stacked. The first base layer 101 and the second base layer 103 may each include polyimide (PI), polyethersulfone (PES), polyacrylate, polyetherimide (PEI), polyethylene naphthalate (PEN), polyethylene terephthalate (PET), polyphenylene sulfide (PPS), polycarbonate (PC), cellulose tri acetate (TAC), and/or cellulose acetate propionate (CAP). The first barrier layer 102 and the second barrier layer 104 may each include an inorganic insulating material such as silicon oxide, silicon oxynitride, and/or silicon nitride. The substrate 100 may be flexible.

The pixel circuit layer PCL may be disposed on the substrate 10. It is shown in FIG. 20 that the pixel circuit layer PCL includes a thin-film transistor TFT, a buffer layer 111, a first gate insulating layer 112, a second gate insulating layer 113, an interlayer insulating layer 114, and a first planarization insulating layer 115, and a second planarization insulating layer 116 under and/or on elements of the thin-film transistor TFT.

The buffer layer 111 may reduce or block penetration of foreign materials, moisture, or external air from below the substrate 100 and provide a flat surface on the substrate 100. The buffer layer 111 may include an inorganic insulating material such as silicon nitride, silicon oxynitride, and/or silicon oxide, and include a single-layered structure or a multi-layered structure including the above materials.

The thin-film transistor TFT on the buffer layer 111 may include a semiconductor layer Act, and the semiconductor layer Act may include polycrystalline silicon. In other embodiments, the semiconductor layer Act may include amorphous silicon, an oxide semiconductor, and/or an organic semiconductor. The semiconductor layer Act may include a channel region C, a drain region D, and a source region S respectively arranged on two opposite sides of the channel region C. A gate electrode GE may overlap the channel region C.

The gate electrode GE may include a low-resistance metal material. The gate electrode GE may include a conductive material including molybdenum (Mo), aluminum (Al), copper (Cu), and/or titanium (Ti) and have a single-layered structure or a multi-layered structure including the above materials.

The gate insulating layer 112 between the semiconductor layer Act and the gate electrode GE may include an inorganic insulating material including silicon oxide (SiO₂), silicon nitride (SiNₓ), silicon oxynitride (SiON), aluminum oxide (Al₂O₃), titanium oxide (TiO₂), tantalum oxide (Ta₂O₅), hafnium oxide (HfO₂), and/or zinc oxide (ZnOₓ). Zinc oxide (ZnOₓ) may be zinc oxide (ZnO) and/or zinc peroxide (ZnO₂).

The second gate insulating layer 113 may cover the gate electrode GE. Similar to the first gate insulating layer 112, the second gate insulating layer 113 may include an inorganic insulating material including silicon oxide (SiO₂), silicon nitride (SiNₓ), silicon oxynitride (SiON), aluminum oxide (Al₂O₃), titanium oxide (TiO₂), tantalum oxide (Ta₂O₅), hafnium oxide (HfO₂), and/or zinc oxide (ZnOₓ). Zinc oxide (ZnOₓ) may be zinc oxide (ZnO) and/or zinc peroxide (ZnO₂).

An upper electrode Cst2 of the storage capacitor Cst may be arranged on the second gate insulating layer 113. The upper electrode Cst2 may overlap the gate electrode GE therebelow. The gate electrode GE and the upper electrode Cst2 overlapping each other with the second gate insulating layer 113 therebetween, may constitute the storage capacitor Cst. For example, the gate electrode GE may serve as a lower electrode Cst1 of the storage capacitor Cst.

As described above, the storage capacitor Cst may overlap the thin-film transistor TFT. In an embodiment, the storage capacitor Cst may be formed not to overlap the thin-film transistor TFT.

The upper electrode Cst2 may include aluminum (Al), platinum (Pt), palladium (Pd), silver (Ag), magnesium (Mg), gold (Au), nickel (Ni), neodymium (Nd), iridium (Ir), chrome (Cr), calcium (Ca), molybdenum (Mo), titanium (Ti), tungsten (W), and/or copper (Cu), and include a single layer or a multi-layer including the above materials.

The interlayer insulating layer 114 may cover the upper electrode Cst2. The interlayer insulating layer 114 may include silicon oxide (SiO₂), silicon nitride (SiNₓ), silicon oxynitride (SiON), aluminum oxide (Al₂O₃), titanium oxide (TiO₂), tantalum oxide (Ta₂O₅), hafnium oxide (HfO₂), and/or zinc oxide (ZnOₓ). Zinc oxide (ZnOₓ) may be zinc oxide (ZnO) and/or zinc peroxide (ZnO₂). The interlayer insulating layer 114 may include a single layer or a multi-layer including the inorganic insulating material.

A drain electrode DE and a source electrode SE may each be arranged on the interlayer insulating layer 114. The drain electrode DE and the source electrode SE may be respectively connected to the drain region D and the source region S through contact holes of insulating layers therebelow. The drain electrode DE and the source electrode SE may each include a material having high conductivity. The drain electrode DE and the source electrode SE may each include a conductive material including molybdenum (Mo), aluminum (Al), copper (Cu), and/or titanium (Ti) and include a single layer or a multi-layer including the above materials. In an embodiment, the drain electrode DE and the source electrode SE may each have a multi-layered structure of Ti/Al/Ti.

The first planarization insulating layer 115 may cover the drain electrode DE and the source electrode SE. The first planarization insulating layer 115 may include an organic insulating material including a general-purpose polymer such as polymethylmethacrylate (PMMA) or polystyrene (PS), polymer derivatives having a phenol-based group, an acryl-based polymer, an imide-based polymer, an aryl ether-based polymer, an amide-based polymer, a fluorine-based polymer, a p-xylene-based polymer, a vinyl alcohol-based polymer, or a blend thereof.

The second planarization insulating layer 116 may be disposed on the first planarization insulating layer 115. The second planarization insulating layer 116 may include the same material as a material of the first planarization insulating layer 115 and may include an organic insulating material including a general-purpose polymer such as polymethylmethacrylate (PMMA) or polystyrene (PS), polymer derivatives having a phenol-based group, an acryl-based polymer, an imide-based polymer, an aryl ether-based polymer, an amide-based polymer, a fluorine-based polymer, a p-xylene-based polymer, a vinyl alcohol-based polymer, or a blend thereof.

The display element layer DEL may be disposed on the pixel circuit layer PCL having the above structure. The display element layer DEL may include an organic light-emitting diode OLED as a display element (that is, a light-emitting element). The organic light-emitting diode OLED may have a stack structure of a pixel electrode 210, an intermediate layer 220, and a common electrode 230. The organic light-emitting diode OLED may be configured to emit, for example, red, green, or blue light, or emit red, green, blue, or white light. The organic light-emitting diode OLED may be configured to emit light through an emission area. The emission area may be defined as a pixel PX.

The pixel electrode 210 of the organic light-emitting diode OLED may be electrically connected to the thin-film transistor TFT through contact holes formed in the second planarization insulating layer 116 and the first planarization insulating layer 115, and a contact metal CM disposed on the first planarization insulating layer 115.

The pixel electrode 210 may include a conductive oxide such as indium tin oxide (ITO), indium zinc oxide (IZO), zinc oxide (ZnO), indium oxide (In₂O₃), indium gallium oxide (IGO), and/or aluminum zinc oxide (AZO). In another embodiment, the pixel electrode 210 may include a reflective layer including silver (Ag), magnesium (Mg), aluminum (Al), platinum (Pt), palladium (Pd), gold (Au), nickel (Ni), neodymium (Nd), iridium (Ir), chrome (Cr), or a compound thereof. In another embodiment, the pixel electrode 210 may further include a layer on/under the reflective layer, the layer including ITO, IZO, ZnO, and/or In₂O₃.

A pixel-defining layer 117 may be disposed on the pixel electrode 210, the pixel-defining layer 117 including an opening 1170P exposing a central portion of the pixel electrode 210. The pixel-defining layer 117 may include an organic insulating material and/or an inorganic insulating material. The opening 1170P may define the emission area of light emitted from the organic light-emitting diode OLED. As an example, the size/width of the opening 1170P may correspond to the size/width of the emission area. Accordingly, the size and/or width of the pixel PX may depend on the size and/or width of the opening 1170P of the pixel-defining layer 117.

The intermediate layer 220 may include an emission layer 222 formed to correspond to the pixel electrode 210. The emission layer 222 may include a polymer organic material or a low-molecular weight organic material emitting light having a preset color. In other embodiments, the emission layer 222 may include an inorganic emission material or quantum dots.

In an embodiment, the intermediate layer 220 may include a first functional layer 221 and a second functional layer 223 respectively disposed under and on the emission layer 222. The first functional layer 221 may include, for example, a hole transport layer (HTL), or include an HTL and a hole injection layer (HIL). The second functional layer 223 may be an element disposed on the emission layer 222 and may include an electron transport layer (ETL) and/or an electron injection layer (EIL). Like the common electrode 230 described below, the first functional layer 221 and/or the second functional layer 223 may be common layers covering the substrate 100 entirely.

The common electrode 230 may be disposed on the pixel electrode 210 and may overlap the pixel electrode 210. The common electrode 230 may include a conductive material having a low work function. As an example, the common electrode 230 may include a (semi) transparent layer including silver (Ag), magnesium (Mg), aluminum (Al), platinum (Pt), palladium (Pd), gold (Au), nickel (Ni), neodymium (Nd), iridium (Ir), chrome (Cr), or an alloy thereof. In other embodiments, the common electrode 230 may further include a layer on the (semi) transparent layer, the layer including ITO, IZO, ZnO, and/or In₂O₃. The common electrode 230 may be formed as a body to cover the substrate 100 entirely.

The encapsulation layer 300 may be disposed on the display element layer DEL and may cover the display element layer DEL. The encapsulation layer 300 may include at least one inorganic encapsulation layer and at least one organic encapsulation layer. In an embodiment, it is shown in FIG. 20 that the encapsulation layer 300 includes a first inorganic encapsulation layer 310, an organic encapsulation layer 320, and a second inorganic encapsulation layer 330 that are sequentially stacked on each other.

The first inorganic encapsulation layer 310 and the second inorganic encapsulation layer 330 may include at least one inorganic material from among aluminum oxide, titanium oxide, tantalum oxide, hafnium oxide, zinc oxide, silicon oxide, silicon nitride, and silicon oxynitride. The organic encapsulation layer 320 may include a polymer-based material. The polymer-based material may include an acryl-based resin, an epoxy-based resin, polyimide, and/or polyethylene. In an embodiment, the organic encapsulation layer 320 may include acrylate. The organic encapsulation layer 320 may be formed by hardening a monomer or coating a polymer. The organic encapsulation layer 320 may be transparent.

Though not shown, a touch sensor layer may be disposed on the encapsulation layer 300. An optical functional layer may be disposed on the touch sensor layer. The touch sensor layer may obtain coordinate information corresponding to an external input, for example, a touch event. The optical functional layer may reduce the reflectivity of light (external light) incident toward the display apparatus from outside, and/or improve the color purity of light emitted from the display apparatus. In an embodiment, the optical functional layer may include a retarder and/or a polarizer. The retarder may include a film-type retarder or a liquid crystal-type retarder. The retarder may include a λ/2 retarder and/or a λ/4 retarder. The polarizer may include a film-type polarizer or a liquid crystal-type polarizer. The film-type polarizer may include a stretchable synthetic resin film, and the liquid crystal-type polarizer may include liquid crystals arranged in an arrangement. Each of the retarder and the polarizer may further include a protective film.

An adhesive member may be disposed between the touch sensor layer and the optical functional layer. For the adhesive member, a general adhesive member may be employed. The adhesive member may be a pressure sensitive adhesive (PSA).

According to embodiments, transformation of the opening of a mask sheet may be prevented, and thus, a deposition quality of the deposition material may be improved and a shadow phenomenon may be reduced.

The deposition quality may be improved with a reduced time consumed in manufacturing the mask sheet.

Effects of the disclosure are not limited to the above mentioned effects and other effects not mentioned may be clearly understood by those of ordinary skill in the art from the following claims.

It should be understood that embodiments described herein should be considered in a descriptive sense only and not for purposes of limitation. Descriptions of features or aspects within each embodiment should typically be considered as available for other similar features or aspects in other embodiments. While one or more embodiments have been described with reference to the figures, it will be understood by those of ordinary skill in the art that various changes in form and details may be made therein without departing from the spirit and scope of the disclosure.

What is claimed is:

1. A method of manufacturing a mask assembly, the method comprising:
preparing a mask frame including an opening area;
forming an opening of a first group in a first area of a center of a mask sheet;
tensioning and fixing the mask sheet to the mask frame; and
forming an opening of a second group in a second area of the mask sheet, wherein
the second area surrounds the first area.

2. The method of claim 1, wherein the forming of the opening of the first group includes wet-etching the first area.

3. The method of claim 1, wherein the forming of the opening of the second group includes laser-etching the second area.

4. The method of claim 3, wherein the forming of the opening of the second group includes processing the opening of the second group such that the opening of the second group surrounds the first area.

5. The method of claim 4, wherein the forming of the opening of the second group includes sequentially performing the laser-etching in a clockwise or counterclockwise direction around a reference point located in a center of the mask sheet.

6. The method of claim 4, wherein the forming of the opening of the second group includes:
performing the laser-etching to form a first opening; and
performing the laser-etching to form a second opening symmetrical to the first opening with respect to a reference point located in a center of the mask sheet.

7. The method of claim 3, wherein the laser-etching of the second area includes:
laser-etching the second area in a size less than a size of the opening of the second group; and
extending a laser-etched portion to the size of the opening of the second group by using tensile force applied to the mask sheet.

8. The method of claim 1, wherein
the tensioning and fixing of the mask sheet to the mask frame includes welding a third area to the mask frame, and
the third area surrounds the second area of the mask sheet.

9. The method of claim 1, wherein the forming of the opening of the second group includes:
performing wet-etching to form a temporary opening less than a size of the opening of the second group; and
performing laser-etching along a circumference of the temporary opening.

10. The method of claim 9, wherein
the temporary opening is formed in an operation of wet-etching, and
the operation of wet-etching and the wet-etching of forming the opening of the first group are a same operation.

11. The method of claim 9, wherein a shape of the temporary opening and a shape reduced by offsetting a shape of the opening of the second group by a same ratio are same.

12. The method of claim 1, wherein the forming of the opening of the second group includes:
half-etching the second area to correspond to a size of the opening of the second group in a first surface of the mask sheet; and
laser-etching the second area in a second surface of the mask sheet facing the first surface.

13. The method of claim 12, wherein the half-etching of the second area includes half-etching the second area by using a wet-etching method.

14. The method of claim 12, wherein the forming of the opening of the first group includes:
half-etching the first area to correspond to a size of the opening of the first group in the first surface; and
half-etching the first area in the second surface.

15. The method of claim 14, wherein the half-etching of the second area in the first surface and the half-etching of the first area in the first surface are performed in a same process.

16. A method of manufacturing a display apparatus, the method comprising:
preparing a mask assembly;
arranging a display substrate to face the mask assembly; and
passing a deposition material through the mask assembly and depositing the deposition material on the display substrate, the deposition material being supplied from a deposition source, wherein
the preparing of the mask assembly includes:
preparing a mask frame including an opening area;
forming an opening of a first group in a first area of a center of a mask sheet;
tensioning and fixing the mask sheet to the mask frame; and
forming an opening of a second group in a second area of the mask sheet, and
the second area surrounds the first area.

17. The method of claim 16, wherein the forming of the opening of the first group includes wet-etching the first area.

18. The method of claim 16, wherein the forming of the opening of the second group includes laser-etching the second area.

19. A mask assembly comprising:
a mask frame including an opening area; and
a mask sheet disposed within the opening area, wherein
the mask sheet includes:
a first area in a center, having an opening of a first group; and
a second area having an opening of a second group and surrounding the first area,
the first area has a first inclined surface in a thickness direction in a circumference of the opening of the first group,
the second area has a second inclined surface in the thickness direction in a circumference of the opening of the second group, and
an inclined angle of the first inclined surface is different from an inclined angle of the second inclined surface.

20. The mask assembly of claim 19, wherein
the first inclined surface is a curved surface, and
the second inclined surface is a flat surface.
